(19) United States
(12) Patent Application Publication
(10) Pub. No.: US 2006/0214696 A1
(43) Pub. Date: Sep. 28, 2006

(54) Voltage supply structure and method

(76) Inventor: Daniel Timmermans, Eindhoven (NL)

Correspondence Address: PHILIPS INTELLECTUAL PROPERTY & STANDARDS, P.O. BOX 3001, BRIARCLIFF MANOR, NY, 10510, US

(21) Appl. No.: 10/566,764

(22) PCT Filed: Jul. 27, 2004
(86) PCT No.: PCT/IB04/51300

§ 371 Date: Jan. 31, 2006

(30) Foreign Application Priority Data
Aug. 4, 2003 (EP) 03102416.9

(51) Int. Cl. H03K 19/00; H01L 25/00

(52) U.S. Cl. 326/101

(57) ABSTRACT

FIG. 1c shows a logic tree 10c comprising a plurality of logic paths (27, 29, 31, 33) connected at a root 11c. The length of each path represents the delay of the path at a nominal supply voltage. The voltage supply structure for the logic tree 10c is partitioned as shown in FIG. 3c, according to the delay of each logic path. For example, logic path (29) having the worst-case delay is supplied a voltage level V1, for example the nominal supply voltage. Logic paths (27) and (31), having a shorter delay, are supplied a second voltage level V2, which is lower than the first voltage level V1. Logic path (33), having an even shorter delay, is supplied a third voltage level V3, which is lower than V2 and V1. The voltage structure enables the voltage level and hence power consumption to be reduced without increasing the overall worst-case delay of the logic tree 10c.

The invention relates to a voltage supply structure for an integrated circuit, and in particular, to a voltage supply structure which is partitioned such that a logic path of a logic tree operates at a predetermined voltage according to the delay of the logic path.

There is continually a demand to improve the performance of integrated circuits. One such demand is the requirement to reduce power consumption, particularly in portable devices that are powered by a battery. Lowering the power consumption, for example by lowering the operating voltage, enables a device to operate for a prolonged period of time. This technique is particularly effective due to the quadratic dependency of the supply voltage on energy consumption. However, lowering the operating voltage has the degrading effect of slowing the propagation of signals on the integrated circuit, which goes against the general demand for higher operating speeds.

It is known to reduce energy consumption on an integrated circuit using a technique called “voltage scaling”. One method of voltage scaling is based on the assumption that the environmental prescription for the delay of the circuit is larger than the actual worst-case delay of the circuit at a nominal supply voltage. In this situation the circuit can operate at a fixed supply voltage that is less than the nominal voltage, thereby reducing energy consumption without causing degradation of the required performance. Although this technique has the advantage of only requiring level converters at the interface between the two supply voltages, it only provides a limited form of power saving.

Another known technique for reducing the voltage of a circuit is based on the assumption that the environmental prescription for the delay of the circuit changes in time due to a flexible workload imposed by the environment on the circuit. This means that the circuit must sometimes work harder and faster than at other times. This change in demand enables the circuit to operate at a different supply voltage. For example, the supply voltage and corresponding clock frequency can be lowered when the circuit does not have to perform at full speed. However, this type of arrangement suffers from the disadvantage that a considerable amount of time is required to change the supply voltage of the circuit (i.e. depending on both the actual voltage difference and the capacitance of the circuit).

In addition, the technique described above suffers from the disadvantage of having to dynamically change the clock frequency of the circuit, since the cycle time should also dynamically follow the worst-case delay. Thus, any adjustments to the circuit typically involve the introduction of:

a controller for dynamically varying the supply voltage

level converters at the interface towards the environment

a controller for dynamically varying the clock frequency

a so-called clock domain bridge at the interface towards the environment (to allow the clock domain of the circuit to communicate with a possibly different clock domain of the environment).

Another method of voltage scaling is based on the assumption that, when designing a circuit, reducing energy consumption can sometimes be traded for additional area. The additional area is used to duplicate logic trees and corresponding input-registers in the circuit. This enables the circuit to be operated at a fixed supply voltage that causes the worst-case delay of these logic trees to double. By clocking the input registers of these logic trees alternately, the clock frequency of the individual input registers can be halved. Finally, an additional multiplexer is used to recombine the results of both logic trees. Although this method does not affect the throughput of the design to any great extent, it has the disadvantage of introducing extra delay for the multiplexer and the optional level converters that again might be required towards the environment. In addition, this arrangement has the disadvantage of degrading the latency of the logic trees by a factor of two.

The aim of the present invention is to provide a voltage supply structure, and a method of designing a voltage supply structure for an integrated circuit, that do not suffer from the disadvantages mentioned above.

According to a first aspect of the invention there is provided a voltage supply structure for an integrated circuit, the integrated circuit comprising one or more logic trees having a plurality of logic paths, each logic path having an associated delay at a particular voltage level, characterized in that the voltage supply structure is partitioned such that the voltage level supplied to a particular logic path is predetermined according to the delay of that logic path.

The invention has the advantage of enabling each logic path to operate at the lowest acceptable voltage level, thereby saving power consumption.

According to another aspect of the present invention, there is provided a method of designing a voltage supply structure for an integrated circuit comprising one or more logic trees having a plurality of logic paths, each logic path having an associated delay at a particular voltage level, the method comprising the steps of:

selecting a logic tree having two or more logic paths with unequal delays;

determining the delay of each logic path in the selected logic tree at a particular voltage level;

partitioning the voltage supply such that the voltage level supplied to each logic path in the logic tree is based on the delay of the logic path.

For a better understanding of the present invention, and to show more clearly how it may be carried into effect, reference will now be made, by way of example, to the accompanying drawings, in which:

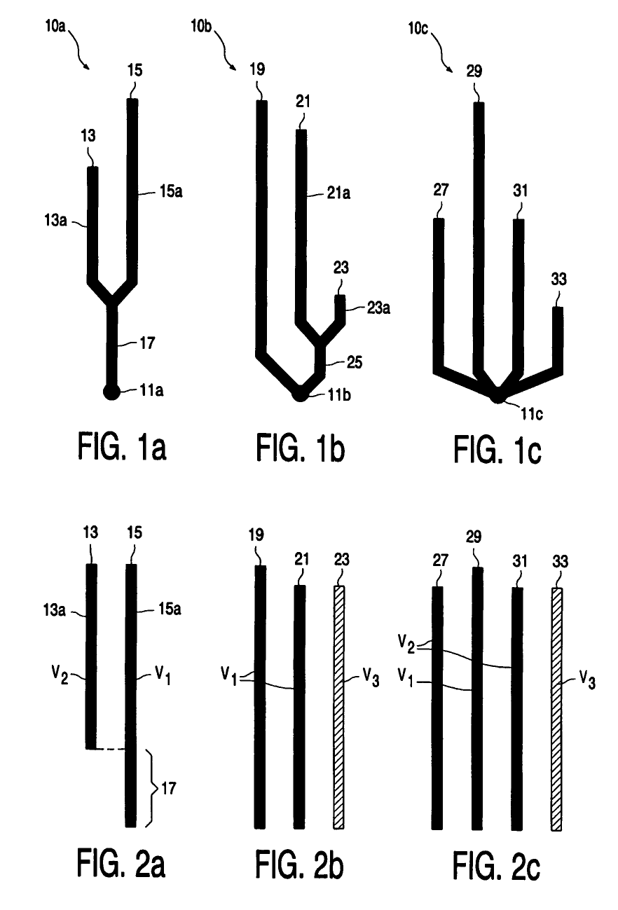

FIGS. 1a, 1b, 1c show typical logic trees having a plurality of logic paths with different delays;

FIGS. 2a, 2b, 2c show how the logic trees of FIG. 1 are partitioned to operate at different supply voltages in accordance with the present invention;

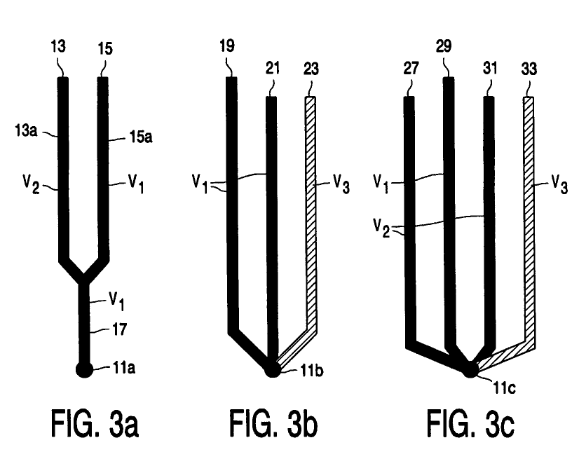

FIGS. 3a, 3b and 3c illustrate alternative ways of partitioning the supply voltage according to different embodiments of the present invention; and

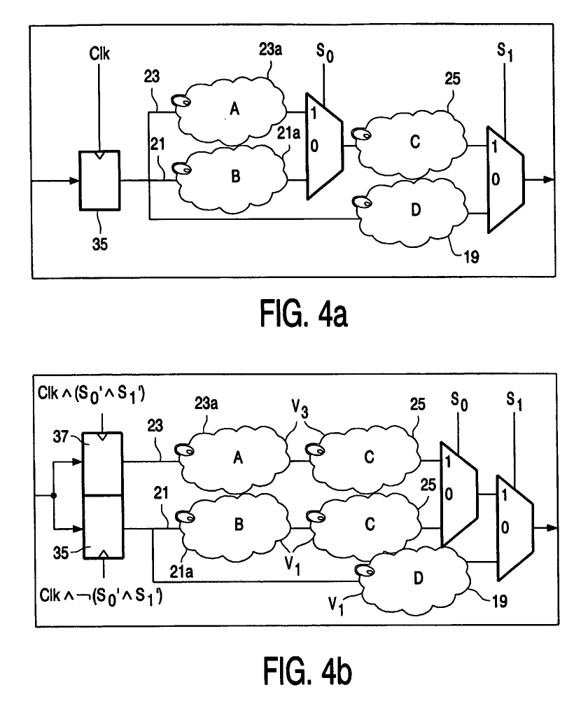

FIGS. 4a and 4b compare a conventional voltage structure with that of the present invention.

FIGS. 1a to 1c show a schematic depiction of an example set of logic trees 10a to 10c. Each node 11a to 11c represents the root of a respective logic tree 10a to 10c. The vertical component of each line-length indicates the delay of that part of the logic tree 10 at a particular voltage level, for example the supply voltage or nominal voltage. FIG. 1a shows a logic tree 10a comprising a first logic path 13 and a second logic path 15. Logic path 13 has a non-overlapping portion 13a and an overlapping portion 17 which is shared with logic path 15. Similarly, logic path 15 has a non-overlapping portion 15a and an overlapping portion 17 which is shared with logic path 13. In other words, logic paths 13, 15 share an overlapping portion 17.

FIG. 1b shows a logic tree 10b comprising logic paths 19, 21, 23, whereby logic paths 21 and 23 share an overlapping portion 25. Logic paths 21, 23 comprise non-overlapping portions 21a and 23a, respectively.

FIG. 1c shows a logic tree 10c comprising logic paths 27, 29, 31, 33. Logic paths 27, 29, 31, 33 have no overlapping portions.

It is noted that the worst-case delay in each logic tree 10a to 10c is fairly well balanced. This means that, according to the prior art, all logic trees 10a to 10c would be configured to operate at the same supply voltage.

However, according to the present invention, the logic paths in logic trees 10a to 10c are partitioned to operate at different supply voltages, as will be explained below with reference to FIGS. 2a to 2c. Referring to FIG. 2c (which corresponds to FIG. 1c in which the logic paths do not have any overlapping portions), the voltage for each logic path 27, 29, 31, 33 is determined according to the worst-case delay of that particular path. For example, logic path 29 which has the longest delay (see FIG. 1c) can be assigned a high supply voltage V1, for example the nominal supply voltage. However, logic path 27 which has a shorter delay (see FIG. 1c), can be assigned a lower supply voltage V2. Likewise, logic path 31 which has a delay similar to that of logic path 27 can also be assigned a supply voltage V2. Logic path 33 having an even shorter delay is assigned a lower supply voltage V3.

Form the above, it can be seen that the invention partitions the logic tree 10c into a plurality of separate logic paths, and assigns a supply voltage to each logic path based on the worst-case delay of that particular logic path. This enables power consumption to be reduced, since the supply voltages applied to individual logic paths within a logic tree can be lowered, thereby enabling the overall power consumption to be reduced. In addition, the application of a different supply voltage to each logic path balances out the delays for the respective logic paths.

When a logic tree comprises logic paths having overlapping portions, for example as shown in FIGS. 1a and 1b, the present invention provides alternative ways of partitioning the overlapping portions of the logic paths. For example, according to a first embodiment the overlapping portion can be shared, as will be described in relation to FIG. 2a below. Alternatively, according to another embodiment the overlapping portion can be duplicated, as will be described in relation to FIG. 2b below.

Referring to FIG. 2a, this shows how the overlapping portion 17 in FIG. 1a is shared. The non-overlapping portion 15a of logic path 15 (i.e. having the longest delay) is assigned a first voltage level V1, for example the nominal supply voltage. The overlapping portion 17 that is shared between logic paths 13 and 15 is also assigned the first voltage level, V1. However, since logic path 13 has a shorter delay, the non-overlapping portion 13a is supplied a lower supply voltage, V2. The dotted line indicates where the non-overlapping portion 13a of logic path 13 operating at voltage level V2 should be stable in order to have the shared part of the voltage level V1 be stable within time.

This arrangement has the advantage of preserving the physical dependency between logic paths 13 and 15. However, a disadvantage is that at least one of the logic paths, i.e. logic path 13 in the illustrated example, has multiple portions 13a, 17 operating at their own supply voltage levels V1, V2, respectively. In other words, the overlapping portion 17 of logic path 13 is supplied the higher voltage level V1, while the non-overlapping portion 13a is supplied a lower voltage level V2. Thus, although this arrangement has the advantage of not requiring any additional area on the integrated circuit, the arrangement does not allow the highest possible energy reduction to be achieved.

Referring to FIG. 2b, this shows the second embodiment in which an overlapping portion is duplicated. Logic paths 19 and 21 having the longest delay are configured to operate at the highest voltage level V1. However, since the overlapping portion 25 of FIG. 1b has been duplicated, this enables the whole of logic path 23 (i.e. comprising the non-overlapping portion 23a and overlapping portion 25) to be operated at the lowest supply voltage V3. This arrangement removes the physical dependency entirely, and allows the separate logic paths 19, 21, 23 in the logic tree 10b to be supplied their own fixed supply voltage. Although this arrangement has the drawback of introducing extra area, it does have the advantage of allowing the voltage supply structure to be partitioned such that each logic path 19, 21, 23 is supplied by a separate supply voltage level, thereby enabling the highest energy reduction possible.

Preferably, according to this embodiment, any input registers provided in the circuit are also duplicated, since the introduced logic is likely to ripple (and therefore consume some extra energy) whenever inputs change. Preferably, the input registers are clocked conditionally, only at clock events after which the corresponding logic path is going to be selected. This causes the new hardware to only propagate changes through the logic path when the result is going to be useful. Naturally, the signals that select the result of this path (e.g. multiplexer select-signals or anything similar) can be used to decide which copy of the input registers should actually be clocked.

Now that the paths have been properly partitioned and arranged to receive a corresponding supply voltage as shown in FIGS. 2a to 2c, the logic paths must be recombined in order to remain functionally equivalent to the initial logic trees. FIGS. 3a to 3c shows how the logic paths of the examples shown in FIGS. 2a to 2c can be reconnected into logic trees.

FIG. 3a shows that, logic paths that are partially shared, i.e. having overlapping portions, should be reconnected to each other at the place where the sharing starts. If the different logic paths use different voltage supply levels, for example logic path 13 using voltage V2 and logic path 15 using voltage level V1 in the present example, then level converters are used to allow the different supply voltage domains V1, V2 to communicate. The level converters (not shown) are located at the location previously shown by a dotted line in FIG. 2a, i.e. at the location where the overlapping starts.

Logic paths that are not shared at all should be connected at the root of the logic tree, for example by means of a multiplexer (not shown). As above, if the logic paths are operating at different voltage domains, level converters can be used to allow different supply voltage domains to communicate. The multiplexers can operate at any supply voltage, provided they do not cause the prescribed delay budget to be violated. Preferably, the partition that contains the path with initially the worst-case delay is used as the supply voltage for the multiplexers, since this partition must have the highest supply voltage and therefore introduces the lowest multiplexer delay.

FIG. 3b, relating to the embodiment in which the overlapping portion is duplicated, is reconnected at the root 11b using a multiplexer (not shown). Logic paths 19 and 21 are provided with a supply voltage V1, for example the nominal supply voltage, while logic path 23 is provided with a lower supply voltage V3. As mentioned above, the multiplexer at the root 11b is preferably operated at the highest supply voltage V1.

FIG. 3c shows how logic paths having no overlapping portions are also simply reconnected at the root 11c using a multiplexer (not shown). Thus, as described in FIG. 2c, logic path 29 operates at supply voltage V1, logic paths 27 and 31 operate at supply voltage V2, and logic path 33 operates at supply voltage V3. Again, the multiplexer at the root 11c is preferably operated at the highest supply voltage V1.

FIGS. 4a and 4b show a conventional logic circuit and a logic circuit having a voltage supply structure according to the present invention, respectively. The figures show the adjustments that are made for the logic tree illustrated in FIGS. 1b to 3b above. By convention, clouds represent some form of logic.

FIG. 4a shows a schematic for a conventional situation. The root branches into two paths, here called C and D selected by signal S₁. It is noted that branch C corresponds to the overlapping portion 25 of logic paths 21 and 23 in FIGS. 1b to 3b, while branch D corresponds to the logic path 19. Path C branches into two paths labeled A and B, which are selected by signal S₀. Paths A and B correspond to the non-overlapping portions 23a, 21a, respectively, of logic paths 23 and 21 in FIGS. 1b to 3b. All paths depend on the same set of input registers 35 driven by a clock signal Clk (i.e. there is no duplication of input registers).

FIG. 4b shows a schematic of the same circuit which has been adapted to have a voltage supply structure in accordance with the present invention. The shared path C (i.e. corresponding to section 25) is duplicated and together with path A (i.e. the non-overlapping portion 23a of logic path 23), operates at the lower voltage supply, V3. The logic path BC (i.e. corresponding to the non-overlapping portion 21a of logic path 21 and the overlapping portion 25 in FIG. 3b) operates at the higher voltage level V1, as does path D (corresponding to logic path 19 in FIG. 3b).

Preferably, the input registers 35 are duplicated in the form of duplicate input registers 37, such that path AC receives its own copy of the input registers. The input registers 37 are only clocked if path AC will be used in the next clock cycle (by convention, apostrophes represent the value of its corresponding signal one clock cycle later). Otherwise, the original set of input registers 35 are clocked. It is noted that, if desired, an additional copy of the input registers 35 could also be introduced for path D. Level converters are not shown, but might be necessary between different supply voltages.

Since logic trees are often composed of independent paths that are merely connected through multiplexers at the root, for example as shown in FIGS. 1c, 2c and 3c, this implies that often there is no need to deal with sharing and, more importantly, there is no need to add extra multiplexers to combine the partitions, since these multiplexers are already present. Also, it is noted that, during the separation of logic trees into logic paths, designers do not have to restrict themselves to the use of multiplexers only. For example, logic gates where a faster input determines the output without having to wait for a slower input can be used (e.g. an AND gate that is used to possibly mask off a signal).

The invention described above offers the potential reduction in energy consumption even when the environmental prescription for the delay of the circuit delay is equal to the actual worst-case delay of the circuit at a nominal supply voltage, since it concentrates at logic paths other than the worst-case delay paths. The invention therefore balances the supply voltage for a particular logic path with the worst-case delay of that logic path.

The invention also offers the potential of a reduction in energy consumption even when there is no flexible workload, and it does not require the clock frequency to change dynamically, nor does it require any supply voltage to change dynamically.

Furthermore, the invention offers the potential of a reduction in energy consumption without degrading the latency of the circuit by a significant factor, and it does not require logic trees to be duplicated in their entirety.

Of the alternative ways that have been described to deal with overlapping portions of logic trees, it is noted that the chosen method can depend on a particular application, for example, the “sharing” method can be employed if area is an issue in a design. In addition, it is noted that the various embodiments can be combined in a single application, whereby some of the logic trees deal with overlapping portions using the “sharing” arrangement, whereas other logic trees deal with the overlapping portions using the “duplication” arrangement. For example, if extra area is available near certain logic trees, then the “duplication” arrangement can be used, whereas the “shared” arrangement is used in other sections of the integrated circuit where lack of space is more of an issue. Another reason for using a combined scheme is where the size versus delay of the overlapping portion is an issue. For example, duplicating a relatively large path that has relatively almost no delay might not be justified, and vice-versa.

As can be seen from the above, the invention separates logic paths of logic trees into a number of partitions, whereby each of these partitions operates at a separate (yet fixed) supply voltage. These supply voltages are set such that the worst-case delay of the corresponding partitions matches the clock cycle time.

Although the preferred embodiment has been described using two and three partitioned supply voltages, it is noted that the number of partitions is entirely flexible. For example, a circuit designer can decide how many partitions should be created, bearing in mind the following trade-off between the fact that more partitions result in an increased reduction in power consumption (i.e. due to the fact that paths having different delays can be fitted more closely to a supply voltage for that particular delay), but that more partitions also introduce more supply pins.

1. A voltage supply structure for an integrated circuit, the integrated circuit comprising one or more logic trees having a plurality of logic paths, each logic path having an associated delay at a particular voltage level, characterized in that the voltage supply structure is partitioned such that the voltage level supplied to a particular logic path is predetermined according to the delay of that logic path.

2. A voltage supply structure as claimed in claim 1, wherein the voltage level for each logic path is selected such that each logic path in the logic tree has substantially the same worst-case delay.

3. A voltage supply structure as claimed in claim 1, wherein the voltage level supplied to a particular logic path is predetermined such that the worst-case delay at the supplied voltage level matches a clock cycle time of the integrated circuit.

4. A voltage supply structure as claimed in claim 1, wherein the voltage level supplied to a particular logic path is lowered compared to a nominal voltage level in the integrated circuit, in proportion to the delay of the logic path at the nominal voltage level.

5. A voltage supply structure as claimed in claim 1, wherein the voltage level is lowered in non-critical logic paths.

6. A voltage supply structure as claimed in claim 1, wherein a logic tree comprises first and second logic paths, the first and second logic paths sharing an overlapping portion, whereby the overlapping portion of the logic path is duplicated, and wherein the voltage supply structure is partitioned such that the non-overlapping portion of the first logic path and corresponding duplicated portion is supplied a first voltage level, and wherein the non-overlapping portion of the second logic path and corresponding duplicated portion are supplied a second voltage level.

7. A voltage supply structure as claimed in claim 6, whereby an input register to the overlapping portion of the logic path is duplicated, such that the duplicated logic path receives data from the duplicated input register.

8. A voltage supply structure as claimed in claim 7, wherein the input register and duplicate input register are clocked conditionally, such that the input register for a particular path is only clocked at events after which the corresponding path is going to be selected.

9. A voltage supply structure as claimed in claim 6, wherein the plurality of logic paths are connected at a root of a logic tree.

10. A voltage supply structure as claimed in claim 9, wherein the plurality of logic paths are connected at the root using a multiplexer.

11. A voltage supply structure as claimed in claim 10, wherein the multiplexer is supplied with a voltage level corresponding to the voltage level supplied to the logic path having the worst-case delay.

12. A voltage supply structure as claimed in claim 1, wherein a logic tree comprises first and second logic paths, the first and second logic paths sharing an overlapping portion, whereby the voltage supply structure is partitioned such that the non-overlapping portion of the first logic path is-supplied a first voltage level and the non-overlapping portion of the second logic path is supplied a second voltage level, and wherein the overlapping portion is supplied a voltage level corresponding to the higher of the first and second voltage levels.

13. A voltage supply structure as claimed in claim 12, wherein the first and second logic paths are connected using a level converter at the location where the overlapping portion commences.

14. A voltage supply structure as claimed in claim 1, further comprising level converters for interfacing between logic paths having different voltage levels.

15. A method of designing a voltage supply structure for an integrated circuit comprising one or more logic trees having a plurality of logic paths, each logic path having an associated delay at a particular voltage level, the method comprising the steps of:
selecting a logic tree having two or more logic paths with unequal delays;
determining the delay of each logic path in the selected logic tree at a particular voltage level;
partitioning the voltage supply such that the voltage level supplied to each logic path in the logic tree is based on the delay of the logic path.

16. A method as claimed in claim 15, wherein the voltage level for each logic path is selected such that each logic path in the logic tree has substantially the same worst-case delay.

17. A method as claimed in claim 15, wherein the voltage level supplied to a particular logic path is predetermined such that the worst-case delay at the supplied voltage level matches a clock cycle time of the integrated circuit.

18. A method as claimed in claim 15, wherein the voltage level supplied to a particular logic path is lowered compared to a nominal voltage level on the integrated circuit, in proportion to the delay of the logic path at the nominal voltage level.

19. A method as claimed in claim 15, wherein the voltage level is lowered in non-critical logic paths.

20. A method as claimed in claim 15, whereby a logic tree comprises first and second logic paths, the first and second logic paths sharing an overlapping portion, and further comprising the step of duplicating the overlapping portion of the logic path, and partitioning the voltage supply structure such that the non-overlapping portion of the first logic path and the corresponding duplicated portion is supplied a first voltage level, and wherein the non-overlapping portion of the second logic path and corresponding duplicated portion are supplied a second voltage level.

21. A method as claimed in claim 20, further comprising the step of duplicating an input register to the overlapping portion of the logic path, such that the duplicated logic path receives data from the duplicated input register.

22. A method as claimed in claim 21, wherein the input register and duplicate input register are clocked conditionally, such that the input register for a particular path is only clocked at events after which the corresponding path is going to be selected.

23. A method as claimed in claim 20, wherein the plurality of logic paths are connected at a root of a logic tree.

24. A method as claimed in claim 23, wherein the plurality of logic paths are connected at the root using a multiplexer.

25. A method as claimed in claim 24, wherein the multiplexer is supplied with a voltage level corresponding to the voltage level supplied to the logic path having the worst-case delay.

26. A method as claimed in claim 15, wherein a logic tree comprises first and second logic paths, the first and second logic paths sharing an overlapping portion, further comprising the step of partitioning the voltage supply structure such that the non-overlapping portion of the first logic path is supplied a first voltage level and the non-overlapping portion of the second logic path is supplied a second voltage level, and wherein the overlapping portion is supplied a voltage level corresponding to the higher of the first and second voltage levels.

27. A method as claimed in claim 26, further comprising the step of providing a level converter for connecting the first and second logic paths at the location where the overlapping portion commences.

28. A method as claimed in claim 15, further comprising the step of providing level converters at interfaces between logic paths having different voltage levels.
